(19) United States
(12) Patent Application Publication
(10) Pub. No.: US 2026/0075959 A1
(43) Pub. Date: Mar. 12, 2026

(54) SEMICONDUCTOR DEVICE FOR ESD PROTECTION AND CAN PROTECTION CIRCUIT INCLUDING THE SAME

(71) Applicant: SK keyfoundry Inc., Cheongju-si (KR)

(72) Inventors: Hee Hwan JI, Daejeon (KR); Eun Kyung PARK, Cheongju-si (KR); Gyeong Sun PARK, Seoul (KR)

(73) Assignee: SK keyfoundry Inc., Cheongju-si (KR)

(21) Appl. No.: 19/169,141

(22) Filed: Apr. 3, 2025

(30) Foreign Application Priority Data
Sep. 12, 2024 (KR) 10-2024-0124885

(51) Int. Cl. H10D 89/60

(52) U.S. Cl. CPC H10D 89/713

(57) ABSTRACT

A semiconductor device for ESD protection includes semiconductor substrate, an element isolation layer, and a first well region of a second conductivity type, and second and third well regions of a first conductivity type. The first, second and third well regions are formed below the element isolation layer and are spatially separated from each other. Three doped regions are formed on the first well region and connected to a voltage node (VN) terminal. Two doped regions are formed on the second well region and connected to a ground (GND) terminal. Two doped regions are formed on the third well region and connected to a power supply (VCC) terminal, and the semiconductor device is configured to perform a unidirectional silicon controlled rectifier (SCR) function between the VN terminal and the VCC terminal, and a bidirectional SCR function between the VCC terminal and the GND terminal.

### CROSS-REFERENCE TO RELATED APPLICATION

This application claims the benefit under 35 U.S. C. § 119(a) of Korean Patent Application No. 10-2024-0124885, filed on Sep. 12, 2024, the entire disclosure of which is incorporated herein by reference for all purposes.

### BACKGROUND

### 1. Field

The following description relates to a semiconductor device, and more particularly, to a semiconductor device for ESD protection and controller area network (CAN) protection circuit including the same.

### 2. Description of Related Art

The statements in this section merely provide background information related to the present disclosure and do not necessarily constitute prior art.

A semiconductor device SCR (Silicon Controlled Rectifier) is known as a high voltage electrostatic discharge (ESD) protection device. The SCR device is intended to protect semiconductor IC devices from potential ESD damage. Electrical Overstress (EOS) caused by ESD can cause permanent damage to the unprotected integrated circuits (ICs) of electronic devices and systems. Damage to the integrated circuits (ICs) of electronic devices and systems can lead to abnormal operation of electronic products.

Such SCR devices can be classified into unidirectional SCRs, which have the characteristic of being triggered in one direction, and bidirectional SCRs, which have the characteristic of being triggered in both directions. However, these unidirectional SCRs and bidirectional SCRs are generally used for predetermined applications, so their scope of use is limited.

Therefore, there is a need to develop a new type of SCR device that integrates the functions of unidirectional and bidirectional SCRs. For example, a bidirectional SCR device is used in the protection circuits for automotive Controller Area Network (CAN) transceivers. Due to the structural requirements of the pin terminals in these CAN transceiver protection circuits, six bidirectional SCR devices must be used. This requirement has been a major obstacle to reducing the size of CAN transceiver protection circuits, making it difficult to miniaturize these circuits.

In addition, conventional SCR devices generally have relatively high trigger voltages. When the trigger voltage is high, the holding voltage will be low, increasing the likelihood of latch-up, and making it difficult to apply such a device to actual products. In other words, due to the structural characteristics of the SCR device for ESD protection, the holding voltage is low, and under normal operating conditions, unintended latch-up may occur due to overvoltage or noise that is ESD.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a semiconductor device includes: a first conductivity type semiconductor substrate; an element isolation layer formed on the semiconductor substrate; and a first well region of a second conductivity type, a second well region of the first conductivity type, and a third well region of the first conductivity type. The first well region, the second well region, and the third well region are formed below the element isolation layer and are spatially separated from each other. Three doped regions are formed on the first well region and connected to a voltage node (VN) terminal. Two doped regions are formed on the second well region and connected to a ground (GND) terminal. Two doped regions are formed on the third well region and connected to a power supply (VCC) terminal. The semiconductor device is configured to perform a unidirectional silicon controlled rectifier (SCR) function between the VN terminal and the VCC terminal, and a bidirectional SCR function between the VCC terminal and the GND terminal.

The three doped regions may include: a first doped region of the second conductivity type at a center; and second and third doped regions of the first conductivity type symmetrically formed on left and right sides of the doped region of the second conductivity type.

The second and third doped regions of the first conductivity type may be formed with a smaller length than the first doped region of the second conductivity type.

The two doped regions formed on the second well region or the third well region may include a first doped region of the first conductivity type and a second doped region of the second conductivity type. The first doped region of the first conductivity type may be formed with a smaller length than the doped region of the second conductivity type.

The first conductivity type semiconductor substrate may further include: a buried layer of the second conductivity type; and an epitaxial layer of the first conductivity type.

The semiconductor device may further include a deep well region of the second conductivity type formed below the first well region. The deep well region of the second conductivity type may be configured to connect the first well region to the buried layer of the second conductivity type.

In another general aspect, a semiconductor device includes: a first conductivity type semiconductor substrate; an element isolation layer formed on the semiconductor substrate; a well region of a second conductivity type formed below the element isolation layer; a first body region and a second body region of the first conductivity type symmetrically formed on left and right sides of the well region; a doped region of the second conductivity type formed in each of the first body region and the second body region; and a first doped region of the second conductivity type formed at a center of the well region, and second and third doped regions of the first conductivity type symmetrically formed on left and right sides of the first doped region of the second conductivity type in the well region. In each of the first body region and the second body region, no doped region of the first conductivity type is formed.

The semiconductor device may further include a first well region and a second well region formed in each of the first body region and the second body region. The first body region and the second body region may have higher doping concentrations and may be formed deeper than the first well region and the second well region.

The well region may include no doped regions formed therein.

The first body region may be connected to a GND terminal and the second body region may be connected to an IO terminal, such that the semiconductor device is configured to operate as a bidirectional SCR device when a surge voltage is applied.

The first conductivity type semiconductor substrate may further include: a buried layer of the second conductivity type; an epitaxial layer of the first conductivity type; and a deep well region of the second conductivity type formed below the well region.

In another general aspect, a semiconductor device includes: a first conductivity type semiconductor substrate; an element isolation layer formed on the semiconductor substrate; a well region of a second conductivity type formed below the element isolation layer; and a first body region and a second body region of the first conductivity type formed symmetrically on left and right sides of the well region below the element isolation layer; a doped region of the second conductivity type formed in each of the first body region and the second body region. No doped region of the first conductivity type may be formed in each of the first and second body regions; and a first doped region of the second conductivity type formed at a center of the well region, and second and third doped regions of the first conductivity type formed symmetrically on left and right sides of the first doped region of the second conductivity type in the well region.

Portions of the first body region and the second body region where the first conductivity type is not formed may operate as a resistor.

The well region may be connected to a voltage node (VN) terminal. The first body region may be connected to a ground (GND) terminal. The second body region may be connected to a power supply (VCC) terminal. The semiconductor device may be configured to perform a unidirectional SCR function between the VN terminal and the VCC terminal, and the semiconductor device may be configured to perform a bidirectional SCR function between the VCC terminal and the GND terminal.

The first conductivity type semiconductor substrate may include: a buried layer of the second conductivity type; an epitaxial layer of the first conductivity type; and a deep well region of the second conductivity type formed below the well region.

In another general aspect, a controller area network (CAN) protection circuit includes a first semiconductor device and a second semiconductor device. Each of the first semiconductor device and the second semiconductor device includes: a well region of a second conductivity type formed in a semiconductor substrate of a first conductivity type; and three doped regions formed in the well region and commonly connected to a voltage node (VN) terminal. The three doped regions include: a first doped region of the second conductivity type at center; and second and third doped regions of the first conductivity type symmetrically formed on left and right sides of the first doped region of the second conductivity type. VN terminals of the first semiconductor device and the second semiconductor device are connected to each other via a metallic connection.

One of the first semiconductor device and the second semiconductor device may be connected between a VCC terminal and a CAN High terminal, and the other of the first semiconductor device and the second semiconductor device may be connected between the CAN High terminal and a GND terminal.

The CAN protection circuit may further include a CAN transceiver having a VCC terminal, a CAN High terminal, a CAN Low terminal, and a GND terminal. The first semiconductor device may be connected between the VCC terminal and the CAN High terminal. The second semiconductor device may be connected between the CAN Low terminal and the GND terminal.

According to the present disclosure, the front side and the back side of a semiconductor wafer may be easily connected by a simple etching operation, thereby enabling the manufacture of devices with through structures to be performed more efficiently than in the past.

Other features and aspects will be apparent from the following detailed description, the drawings, and the claims.

### BRIEF DESCRIPTION OF THE DRAWINGS

FIG. 1 illustrates a cross-sectional view of a semiconductor device for ESD protection according to an example of the present disclosure.

FIG. 2 illustrates a configuration diagram of a conventional CAN protection circuit using a bidirectional SCR device.

FIG. 3 illustrates a configuration diagram showing the connection of semiconductor devices used to construct a CAN protection circuit, according to an example of the present disclosure.

FIG. 4 illustrates a configuration diagram of a CAN protection circuit according to an example of the present disclosure, for comparison with the prior art shown in FIG. 2.

FIG. 5 illustrates a diagram illustrating an operation of a CAN protection circuit with respect to an ESD discharge path.

FIG. 6 illustrates a cross-sectional view of a semiconductor device for ESD protection according to another example of the present disclosure.

FIG. 7 illustrates a cross-sectional view of a semiconductor device for ESD protection according to another example of the present disclosure.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto. The use of the term “may” herein with respect to an example or embodiment, e.g., as to what an example or embodiment may include or implement, means that at least one example or embodiment exists where such a feature is included or implemented, while all examples are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The present disclosure provides an SCR device for ESD protection with a new hybrid structure by integrating a unidirectional SCR and a bidirectional SCR into a single device. Through this configuration, miniaturization of CAN transceiver protection circuits can be achieved.

The present disclosure also provides an SCR device for ESD protection with a lower trigger voltage compared to conventional devices.

The technical problems addressed by the present disclosures are not limited to those mentioned above. Additional technical problems not explicitly stated will become apparent to those skilled in the art from the descriptions provided below.

A detailed description is given below, with reference to attached drawings.

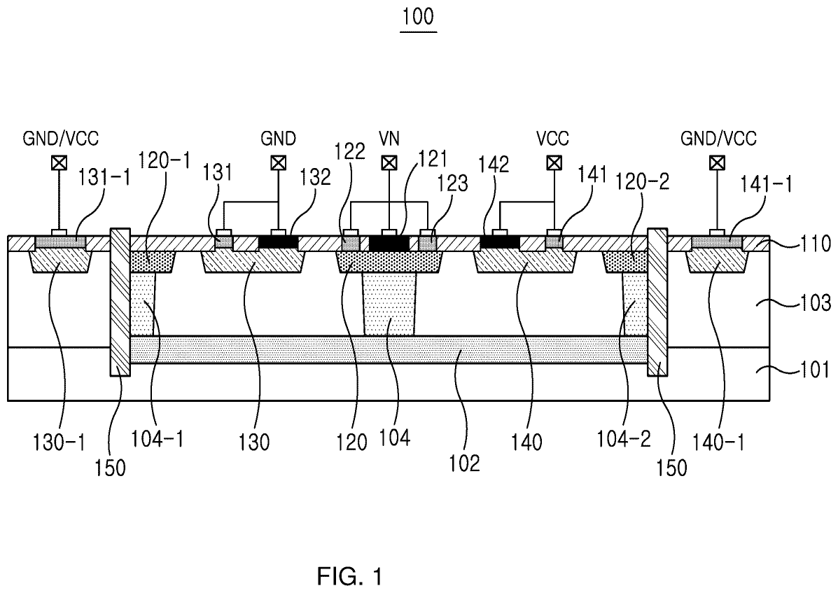

FIG. 1 illustrates a cross-sectional view of a semiconductor device for ESD protection according to an example of the present disclosure.

Referring to FIG. 1, a semiconductor device 100 includes a P-type substrate 101. In the P-type substrate 101, an N-type buried layer (NBL) 102 doped with a high concentration of N-type impurities and a P-type epitaxial layer 103 are formed. The P-type epitaxial layer 103 may be formed through an epitaxial growth process. Additionally, a P-type buried layer (PBL) may also be formed, if necessary.

On the P-type epitaxial layer 103, an element isolation layer 110 is formed. The element isolation layer 110 may have either a Shallow Trench Isolation (STI) structure or a Local Oxidation of Silicon (LOCOS) structure and may be formed of an oxide layer.

The P-type epitaxial layer 103 includes a first well region 120, a second well region 130, and a third well region 140. The first well region 120, second well region 130, and third well region 140 may be formed deeper than the lower portion of the element isolation layer 110. The first well region 120 may be of N-type, while the second well region 130 and the third well region 140 may be of P-type. Hereinafter, the first well region 120 may also be referred to as NW, the second well region 130 as a first PW, and the third well region 140 as a second PW. The second well region 130 and the third well region 140 may be formed spaced apart in opposite directions with respect to the first well region 120 as the center. The first well region 120 and the second well region 130 are spaced apart by a predetermined distance, and the first well region 120 and the third well region 140 are also spaced apart by a predetermined distance. The first well region 120, the second well region 130, and the third well region 140 may be formed with sizes that are substantially similar.

The P-type epitaxial layer 103 further includes an N-type deep well region (DNW) 104 that connects the first well region 120 to the N-type buried layer (NBL) 102. The N-type deep well region 104 may be formed under the first well region 120 within the P-type epitaxial layer 103 and is formed to contact the N-type buried layer 102.

The first well region 120, the second well region 130, and the third well region 140 may include doped regions. Specifically, in the first well region 120, an N+ region 121 and P+ regions 122, 123 are formed. The N+ region 121 is formed at the center, and the P+ regions 122, 123 are symmetrically formed to the left and right of the N+ region 121. The N+ region 121 and the P+ regions 122, 123 are formed separately from each other and are located in the active regions between the isolation layers 110. In this example, the N+ region 121 is formed with a larger length than the P+ regions 122, 123. This configuration allows the larger N+ region, which has a higher doping concentration, to reduce resistance. Both the N+ region 121 and the P+ regions 122, 123 are connected to a single voltage node (VN) terminal.

In the second well region 130, a P+ region 131 and an N+ region 132 are formed. The P+ region 131 and the N+ region 132 in the second well region 130 are connected to a ground (GND) terminal. In the second well region 130, the P+ region 131 is formed with a smaller length than the N+ region 132. Forming the P+ region 131 smaller allows current to flow more effectively and enhances the operational characteristics of the SCR device.

In the third well region 140, a P+ region 141 and an N+ region 142 are formed. The third well region 140 has a structure symmetric to the second well region 130. The N+ region 142 and the P+ region 141 in the third well region 140, similar to those in the second well region 130, are formed such that the P+ region 141 is formed with a smaller length than the N+ region 142. The P+ region 141 and the N+ region 142 in the third well region 140 are connected to a VCC terminal.

The semiconductor device 100 further includes a deep trench isolation (DTI) 150 formed from the surface of the substrate 101 to the N-type buried layer 102 to achieve isolation. As shown in the drawing, NWs 120-1, 120-2 are formed along the sidewalls of the DTI 150, with N-type deep well regions DNWs 104-1, 104-2 connecting the NWs 120-1, 120-2 to the N-type buried layer 102. Outside of the DTI 150, a fourth well 130-1 and a fifth well 140-1 are formed, and high-concentration doping regions 131-1, 141-1 are positioned above the fourth well and fifth wells 130-1, 140-1. The high-concentration doping regions 131-1, 141-1 are configured to be connected to the GND terminal or the VCC terminal. For example, when the fourth and fifth wells 130-1, 140-1 and the high-concentration doping regions 131-1, 141-1 have P-type conductivity, the high-concentration doping regions 131-1, 141-1 are configured to be connected to the GND terminal. Conversely, when the fourth and fifth wells 130-1, 140-1 and the high-concentration doping regions 131-1, 141-1 have N-type conductivity, the high-concentration doping regions 131-1, 141-1 are configured to be connected to the VCC terminal.

The semiconductor device for ESD protection 100 illustrated in FIG. 1 includes both unidirectional SCR and bidirectional SCR structures. When the semiconductor device for ESD protection 100 is implemented as a unidirectional SCR, it can operate between the VN terminal and the VCC terminal. For example, if a positive surge voltage is applied to the VN terminal, the semiconductor device 100 operates as a unidirectional SCR, allowing the surge voltage to be discharged through the VCC terminal. Conversely, when the semiconductor device for ESD protection 100 is implemented as a bidirectional SCR, it can operate bidirectionally between the VCC terminal and the GND terminal via the N-type buried layer 102. For example, if a surge voltage is applied to the VCC terminal, the surge voltage can be discharged to the GND terminal through the third well region 140, the N-type buried layer 102, and the second well region 130.

As described, the semiconductor device for ESD protection 100 in FIG. 1 integrates both the functionality of a unidirectional SCR and a bidirectional SCR into a single device. The semiconductor device for ESD protection of the present disclosure, by providing both functionalities, enables the reduction in size of Controller Area Network (CAN) circuits used in vehicles and other applications. A more detailed explanation is provided below.

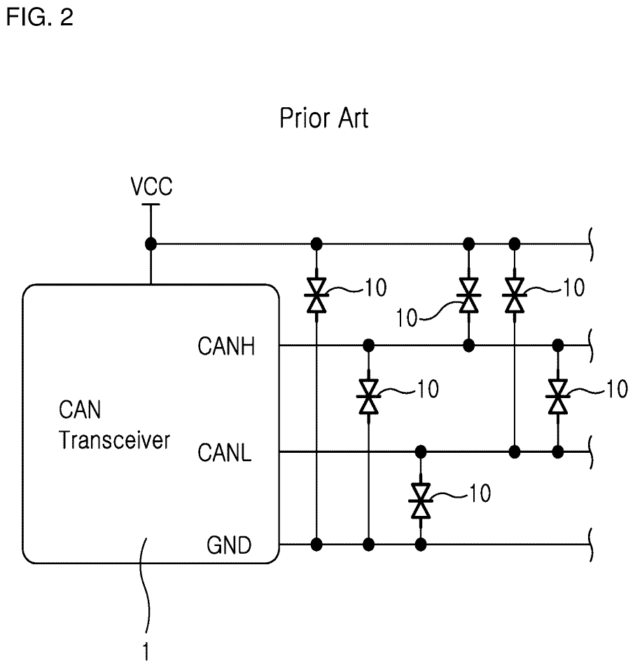

FIG. 2 illustrates a configuration diagram of a conventional CAN protection circuit using a bidirectional SCR device.

Referring to FIG. 2, a CAN transceiver 1 includes four pin terminals: a VCC terminal, a CAN High terminal (CANH), a CAN Low terminal (CANL), and a ground (GND) terminal. A SCR device 10 connected to the CAN transceiver 1 is a bidirectional SCR device, and as shown, a total of six such devices are required.

Specifically, since an automotive CAN protection circuit transmits signals in both positive and negative directions, bidirectional SCR devices are essential for protecting the circuit from ESD. SCR devices 10 are required to connect the following terminal pairs: the VCC terminal and the CAN High terminal, the VCC terminal and the CAN Low terminal, the VCC terminal and the GND terminal, the CAN High terminal and the GND terminal, the CAN Low terminal and the GND terminal, and the CAN High terminal and the CAN Low terminal. Consequently, conventional CAN circuits must be designed to include six bidirectional SCR devices 10, which imposes a limitation on the ability to reduce the overall circuit size.

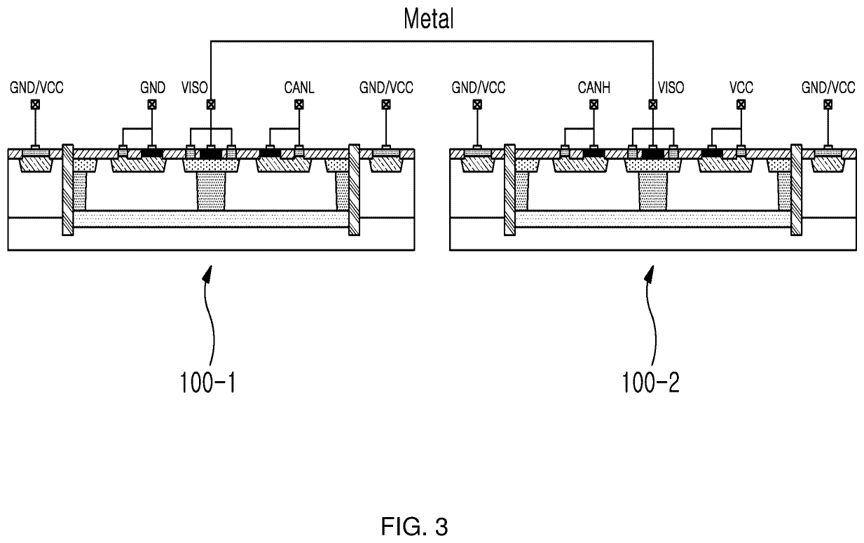

The present example proposes a method to simplify the CAN protection circuit configuration shown in FIG. 2. This simplification can be achieved by connecting the SCR devices described in FIG. 1 as illustrated in FIG. 3.

FIG. 3 illustrates a configuration diagram showing the connection of semiconductor devices to construct a CAN protection circuit according to an example of the present disclosure.

Referring to FIG. 3, the CAN protection circuit includes a first SCR device 100-1 and a second SCR device 100-2, which have identical structures.

The first SCR device 100-1 and the second SCR device 100-2 may include both unidirectional and bidirectional functionalities. As described in FIG. 1, the first SCR device 100-1 and the second SCR device 100-2 are formed with a P-type substrate 101, an N-type buried layer (NBL) 102, and a P-type epitaxial layer 103. Beneath an element isolation film 110 on the upper surface of the P-type substrate 101, first well region to third well region (120 to 140) are formed. The first well region 120 and the N-type buried layer (NBL) 102 are connected by an N-type deep well region (DNW) 104. Additionally, P-N-P doped regions 122, 121, 123 are formed above the first well region 120, and P-N doped regions 131, 141, 132, 142 are formed on the second well region 130 and the third well region 140.

In the first SCR device 100-1, the first well region 120 is connected to an Isolation Voltage (VISO) terminal, the second well region 130 is connected to a GND terminal, and the third well region 140 is connected to a CAN Low terminal. In the second SCR device 100-2, the first well region 120 is connected to the VISO terminal, the second well region 130 is connected to a CAN High terminal, and the third well region 140 is connected to a VCC terminal. Here, the positions of the first SCR device 100-1 and the second SCR device 100-2 may be changed and connected to the terminals. For example, it is possible to connect the first SCR device 100-1 to the VISO (Isolation Voltage) terminal, the CAN High terminal, and the VCC terminal.

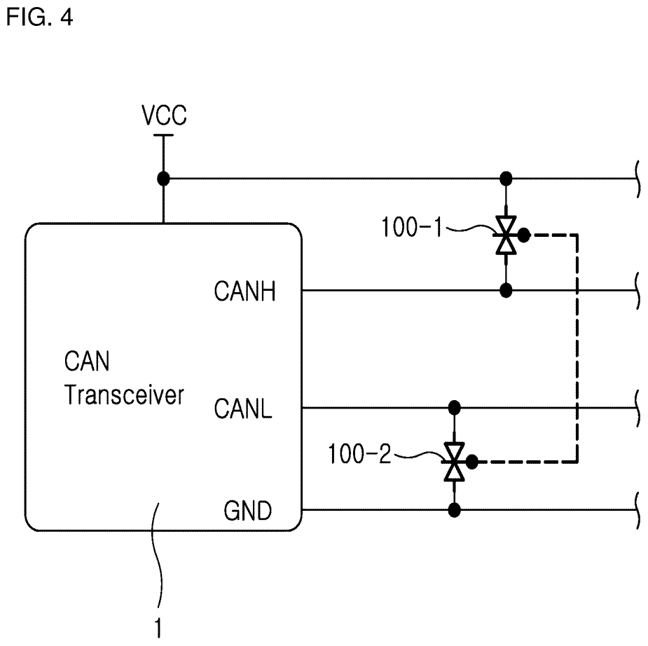

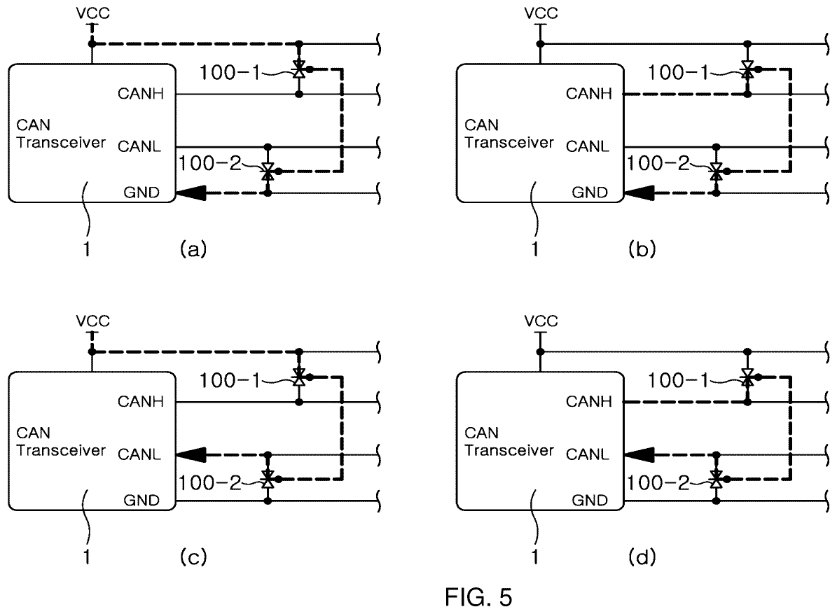

According to this example, by connecting the VISO terminals of the first SCR device 100-1 and the second SCR device 100-2 to each other, the CAN protection circuit can be implemented using only two SCR devices. Further details regarding the CAN protection circuit are explained with reference to FIGS. 4 and 5.

FIG. 4 illustrates a configuration diagram of a CAN protection circuit according to an example of the present disclosure, for comparison with the prior art shown in FIG. 2. FIG. 5 illustrates a diagram illustrating an operation of a CAN protection circuit with respect to an ESD discharge path.

Referring to FIG. 4, in this embodiment, the first SCR device 100-1 is connected between a VCC terminal and a CAN High terminal of a CAN transceiver 1, while the second SCR device 100-2 is connected between a CAN Low terminal and the ground. Additionally, it can be seen that the first SCR device 100-1 and the second SCR device 100-2 are interconnected with metal connections.

Referring to FIG. 5, the operation of the CAN protection circuit of FIG. 4 will now be described.

FIG. 5(a) illustrates a case where a surge voltage is applied to the VCC terminal and flows out through the GND terminal. As shown, when a positive surge voltage is applied to the VCC terminal, the first SCR device 100-1 operates as a diode, and the second SCR device 100-2 operates as a unidirectional SCR, allowing the current to flow to the GND terminal. Conversely, when a negative surge voltage is applied to the VCC terminal, the first SCR device 100-2 operates as a unidirectional SCR, while the second SCR device 100-2 operates as a diode, enabling the current to flow to the GND terminal.

FIG. 5(b) illustrates a case where a surge voltage is applied to the CAN High terminal and flows out through the GND terminal. As shown, when a positive surge voltage is applied to the CAN High terminal, the first SCR device 100-1 operates as a diode, and the second SCR device 100-2 operates as a unidirectional SCR. Conversely, when a negative surge voltage is applied to the CAN High terminal, the first SCR device 100-1 operates as a unidirectional SCR, while the second SCR device 100-2 operates as a diode.

FIG. 5(c) illustrates a case where a surge voltage is applied to the VCC terminal and flows out through the CAN Low terminal. As shown, when a positive surge voltage is applied to the VCC terminal, the first SCR device 100-1 operates as a diode, and the second SCR device 100-2 operates as a unidirectional SCR, allowing the current to flow to the CAN Low terminal. Conversely, when a negative surge voltage is applied to the VCC terminal, the first SCR device 100-1 operates as a unidirectional SCR, while the second SCR device 100-2 operates as a diode, enabling the current to flow to the CAN Low terminal.

FIG. 5(d) illustrates a case where a surge voltage is applied to the CAN High terminal and flows out through the CAN Low terminal. As shown, when a positive surge voltage is applied to the CAN High terminal, the first SCR device 100-1 operates as a diode, and the second SCR device 100-2 operates as a unidirectional SCR, allowing the current to flow to the CAN Low terminal. Conversely, when a negative surge voltage is applied to the CAN High terminal, the first SCR device 100-1 operates as a unidirectional SCR, while the second SCR device 100-2 operates as a diode, enabling the current to flow to the CAN Low terminal.

As described above, according to the present example, it can be understood that the CAN protection circuit can be completely protected from ESD by using only two SCR devices 100, which provide both unidirectional SCR functionality and bidirectional SCR functionality. Therefore, compared to the prior art shown in FIG. 2, which uses six bidirectional SCR devices, the size of the CAN protection circuit can be significantly reduced.

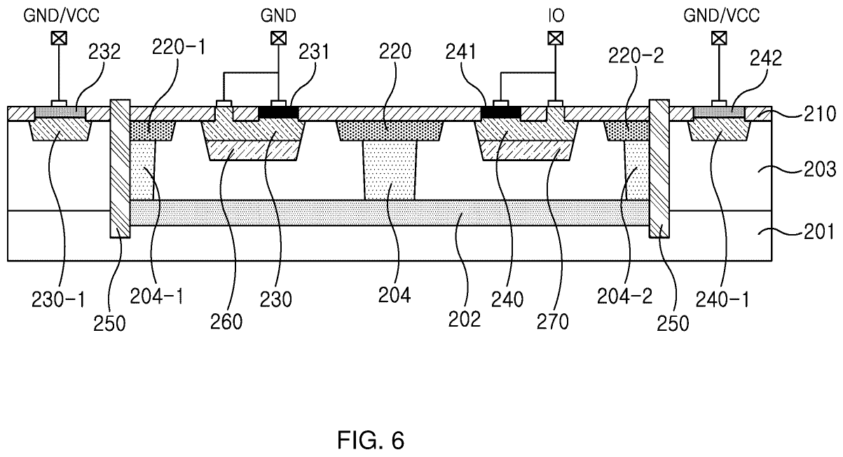

FIG. 6 illustrates a cross-sectional view of a semiconductor device for ESD protection according to another example of the present disclosure.

The semiconductor device for ESD protection 200 shown in FIG. 6 is designed to reduce the trigger voltage to enhance device protection. While it shares overall structural similarities with the semiconductor device shown in FIG. 1, there are notable differences, which are described in detail below.

Referring to FIG. 6, the semiconductor device 200 includes a P-type substrate 201. The P-type substrate 201 comprises an N-type buried layer (NBL) 202 doped with a high concentration of N-type impurities and a P-type epitaxial layer 203. The P-type epitaxial layer 203 can be formed through an epitaxial growth process.

An element isolation layer 210 is formed on the P-type epitaxial layer 203. The element isolation layer 210 may have a Shallow Trench Isolation (STI) structure or a Local Oxidation of Silicon (LOCOS) structure and can be formed of an oxide film.

The P-type epitaxial layer 203 includes an N-well region 220, a first P-well region 230, and a second P-well region 240. The N-well region 220 is formed below the element isolation layer 210. In the N-well region 220, neither N+ regions nor P+ regions, which are doped regions, are formed, and it is covered by the element isolation layer 210. That is, the N-well region 220 has no doped regions and is not connected to any terminal, which is a distinguishing feature compared to the structure shown in FIG. 1.

On the left and right sides of the N-well region 220, the first P-well region 230 and the second P-well region 240 are symmetrically formed. Additionally, a first P-type body region 260 and a second P-type body region 270 are formed. The first P-type body region 260 is similar in width to the first P-well region 230 but is formed deeper. Furthermore, the first P-type body region 260 has a higher doping concentration than the first P-well region 230. Similarly, the second P-type body region 270 has analogous properties. In the first P-type body region 260 and the second P-type body region 270, only N+ regions 231, 241 are formed, and P+ regions are not formed. Compared to FIG. 1, this structure eliminates the P+regions and uses the body regions instead of the well regions. Although the P+ regions are removed, the high-concentration body regions reduce resistance, providing a beneficial effect. Specifically, the P-type body regions 230 and 240 are doped with relatively high concentrations, making it possible to create resistance without the need for P+ doping regions, thereby lowering the trigger voltage. As a result, external resistors are unnecessary for reducing the trigger voltage, allowing for a reduction in the size of the device. The first P-well region 230 and the N+ region 231 are connected to the GND terminal, while the second P-well region 240 and the N+ region 241 are connected to the IO terminal.

To ensure device isolation, a deep trench isolation (DTI) 250 is formed, extending from the surface of the substrate 201 to the N-type buried layer 202. On the sidewalls of the DTI 250, N-well regions 220-1 and 220-2 are formed. Between these N-well regions 220-1, 220-2 and the N-type buried layer 202, N-type deep well (DNW) regions 204-1 and 204-2 are formed. Additionally, outside of the DTI 250, fourth and fifth well regions 230-1, 240-1 are formed. Above these fourth and fifth well regions 230-1, 240-1, high-concentration doping regions 232, 242 are respectively formed, and these high-concentration doping regions 232, 242 are configured to be connected to the GND terminal or the VCC terminal. For example, when the fourth and fifth well regions 230-1, 240-1 and the high-concentration doping regions 232, 242 have P-type conductivity, the high-concentration doping regions 232, 242 are configured to be connected to the GND terminal. Conversely, when the fourth and fifth wells 230-1, 240-1 and the high-concentration doping regions 232, 242 have N-type conductivity, the high-concentration doping regions 232, 242 are configured to be connected to the VCC terminal.

The semiconductor device 200 in FIG. 6 operates solely as a bidirectional SCR device. In FIG. 6, for example, when a surge voltage is applied to the IO terminal, a path is formed through the second P-well region 240, the second P-type body region 270, the N-type buried layer 202, the first P-type body region 260, and the first P-well region 230, allowing the surge to dissipate. As such, the semiconductor device 200 in FIG. 6 operates as a bidirectional SCR device. However, since no P+regions are formed and P-type body regions 260 and 270 with higher doping concentrations than the P-well regions 230 and 240 are implemented, the device achieves the effect of lowering the trigger voltage.

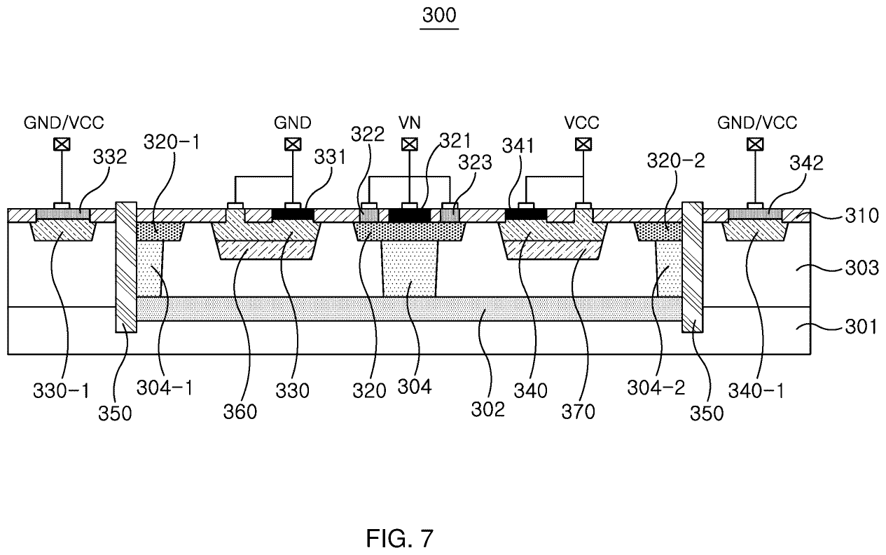

FIG. 7 illustrates a cross-sectional view of a semiconductor device for ESD protection according to another example of the present disclosure. The semiconductor device illustrated in FIG. 7 provides a structure capable of reducing trigger voltage while offering both unidirectional SCR functionality and bidirectional SCR functionality, as shown in FIG. 1.

Referring to FIG. 7, a semiconductor device 300 includes a P-type substrate 301. The P-type substrate 301 includes an N-type buried layer (NBL) 302 doped with a high concentration of N-type impurities and a P-type epitaxial layer 303. The P-type epitaxial layer 303 may be formed through an epitaxial growth process.

An element isolation layer 310 is formed on the P-type epitaxial layer 303. The element isolation layer 310 may have an STI structure or a LOCOS structure. The element isolation layer 310 may be formed as an oxide film.

The P-type epitaxial layer 303 includes an N-well region 320, a first P-well region 330 and a second P-well region 340, which are symmetrically positioned on both sides of the N-well region 320. Additionally, it includes a first-type body region 360 and a second-type body region 370. An N-type deep well region (DNW) 304 is formed below the N-well region 320. The N-type deep well region 304 is formed such that its width narrows progressively toward the N-type buried layer 302 under the N-well region 320.

In the N-well region 320, an N+ region 321 and P+ regions 322, 323 are formed. The N+ region 321 is positioned at the center, with the P+ regions 322, 323 symmetrically located to the left and right of the N+ region 321. The N+ region 321 and the P+ regions 322, 323 are each formed separately. In the example, the N+ region 321 is formed larger than the P+ regions 322, 323 in length. This is to reduce resistance and allow a larger current to flow through the larger N+ region 321. The N+ region 321 and the P+ regions 322, 323 are connected to a VN terminal.

The first P-type body region 360 and the second P-type body region 370 are characterized by being formed deeper than the first P-well region 330 and the second P-well region 340. Additionally, the first P-type body region 360 and the second P-type body region 370 have a higher doping concentration compared to the first P-well region 330 and the second P-well region 340. The first P-well region 330 and the N+ region 331 are connected to the GND terminal, while the second P-well region 340 and the N+ region 341 are connected to the VCC terminal. Furthermore, in the first P-well region 330 and the second P-well region 340, only the N+ regions 331, 341 are formed, and no P+ region is formed. As described previously with reference to FIG. 6, even without forming a P+ doped region, the relatively highly doped P-type body regions 360, 370 can effectively reduce resistance, thereby achieving the desired effect.

For device isolation, a deep trench isolation (DTI) 350 is formed extending from the upper surface of the substrate 301 to the N-type buried layer 302. Along the sidewalls of the DTI 350, N-wells (NW) 320-1, 320-2 are formed. Between the N-wells 320-1, 320-2 and the N-type buried layer 302, N-type deep well regions (DNW) 304-1, 304-2 are formed. Additionally, outside of the DTI 350, fourth and fifth wells 330-1, 340-1 are formed, and high-concentration doping regions 332, 342 are formed on top of the fourth and fifth wells 330-1, 340-1, respectively. The high-concentration doping regions 332, 342 are configured to be connected to the GND terminal or the VCC terminal. For example, when the fourth and fifth well regions 330-1, 340-1 and the high-concentration doping regions 332, 342 have P-type conductivity, the high-concentration doping regions 332, 342 are configured to be connected to the GND terminal. Conversely, when the fourth and fifth wells 330-1, 340-1 and the high-concentration doping regions 332, 342 have N-type conductivity, the high-concentration doping regions 332, 342 are configured to be connected to the VCC terminal.

As described above, the present disclosure provides a hybrid SCR device that integrates both unidirectional SCR and bidirectional SCR into a single component. It can be understood that the use of the hybrid SCR device enables a reduction in the size of CAN protection circuits. Furthermore, the present disclosure also provides an SCR device capable of lowering the trigger voltage.

According to the present disclosure, it is possible to provide a hybrid-structured semiconductor device for ESD protection that integrates both unidirectional SCR and bidirectional SCR functionalities.

According to the present disclosure, when the hybrid-structured semiconductor device for ESD protection of the present disclosure is applied to a protection circuit for an automotive CAN transceiver, it allows for the construction of a CAN protection circuit with fewer components compared to conventional configurations, thereby achieving a reduction in circuit size.

According to the present disclosure, by omitting the formation of doped regions of the same conductivity type in the body region formed in the semiconductor substrate, and instead allowing the unformed regions to operate as resistors, the trigger voltage can be reduced compared to conventional semiconductor devices. Consequently, the invention also prevents latch-up issues that may undesirably occur due to overvoltage or noise.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor device, comprising:
a first conductivity type semiconductor substrate;
an element isolation layer formed on the semiconductor substrate; and
a first well region of a second conductivity type, a second well region of the first conductivity type, and a third well region of the first conductivity type,
wherein the first well region, the second well region, and the third well region are formed below the element isolation layer and are spatially separated from each other;
wherein three doped regions are formed on the first well region and connected to a voltage node (VN) terminal;
wherein two doped regions are formed on the second well region and connected to a ground (GND) terminal;
wherein two doped regions are formed on the third well region and connected to a power supply (VCC) terminal, and
wherein the semiconductor device is configured to perform a unidirectional silicon controlled rectifier (SCR) function between the VN terminal and the VCC terminal, and a bidirectional SCR function between the VCC terminal and the GND terminal.

2. The semiconductor device of claim 1, wherein the three doped regions comprise:
a first doped region of the second conductivity type at a center; and
second and third doped regions of the first conductivity type symmetrically formed on left and right sides of the first doped region of the second conductivity type.

3. The semiconductor device of claim 2, wherein the second and third doped regions of the first conductivity type are formed with a smaller length than the first doped region of the second conductivity type.

4. The semiconductor device of claim 1, wherein the two doped regions formed on the second well region or the third well region comprise:
a first doped region of the first conductivity type and a second doped region of the second conductivity type, and
wherein the first doped region of the first conductivity type is formed with a smaller length than the second doped region of the second conductivity type.

5. The semiconductor device of claim 1, wherein the first conductivity type semiconductor substrate further comprises:
a buried layer of the second conductivity type; and
an epitaxial layer of the first conductivity type.

6. The semiconductor device of claim 5, further comprising:
a deep well region of the second conductivity type disposed below the first well region,
wherein the deep well region of the second conductivity type is configured to connect the first well region to the buried layer of the second conductivity type.

7. A semiconductor device, comprising:
a first conductivity type semiconductor substrate;
an element isolation layer formed on the semiconductor substrate;
a well region of a second conductivity type formed below the element isolation layer;
a first body region and a second body region of the first conductivity type symmetrically formed on left and right sides of the well region; and
a doped region of the second conductivity type formed on each of the first body region and the second body region,
wherein no doped region of the first conductivity type is formed on each of the first body region and the second body region.

8. The semiconductor device of claim 7, further comprising:
a first well region and a second well region formed in each of the first body region and the second body region,
wherein the first body region and the second body region have higher doping concentrations and are formed deeper than the first well region and the second well region.

9. The semiconductor device of claim 7, wherein the well region comprises no doped regions formed therein.

10. The semiconductor device of claim 7, wherein the first body region is connected to a GND terminal and the second body region is connected to an IO terminal, such that the semiconductor device is configured to operate as a bidirectional SCR device when a surge voltage is applied.

11. The semiconductor device of claim 7, wherein the first conductivity type semiconductor substrate further comprises:
a buried layer of the second conductivity type;
an epitaxial layer of the first conductivity type; and
a deep well region of the second conductivity type formed below the well region.

12. A semiconductor device, comprising:
a first conductivity type semiconductor substrate;
an element isolation layer formed on the semiconductor substrate;
a well region of a second conductivity type formed below the element isolation layer;
a first body region and a second body region of the first conductivity type symmetrically formed on left and right sides of the well region below the element isolation layer;
a doped region of the second conductivity type formed in each of the first body region and the second body region, wherein no doped region of the first conductivity type is formed in each of the first and second body regions; and
a first doped region of the second conductivity type formed at a center of the well region, and second and third doped regions of the first conductivity type symmetrically formed on left and right sides of the first doped region of the second conductivity type in the well region.

13. The semiconductor device of claim 12, wherein portions of the first and second body regions where the first conductivity type is not formed operate as a resistor.

14. The semiconductor device of claim 12, wherein the well region is connected to a voltage node (VN) terminal,
wherein the first body region is connected to a ground (GND) terminal,
wherein the second body region is connected to a power supply (VCC) terminal,
wherein the semiconductor device is configured to perform a unidirectional SCR function between the VN terminal and the VCC terminal, and
wherein the semiconductor device is configured to perform a bidirectional SCR function between the VCC terminal and the GND terminal.

15. The semiconductor device of claim 12, wherein the first conductivity type semiconductor substrate comprises:
a buried layer of the second conductivity type;
an epitaxial layer of the first conductivity type; and
a deep well region of the second conductivity type formed below the well region.

16. A controller area network (CAN) protection circuit, comprising:
a first semiconductor device and a second semiconductor device,
wherein each of the first semiconductor device and the second semiconductor device comprises:
a well region of a second conductivity type formed in a semiconductor substrate of a first conductivity type; and
three doped regions formed in the well region and commonly connected to a voltage node (VN) terminal,
wherein the three doped regions comprise:
a first doped region of the second conductivity type at center; and
second and third doped regions of the first conductivity type symmetrically formed on left and right sides of the first doped region of the second conductivity type, and
wherein VN terminals of the first semiconductor device and the second semiconductor device are connected to each other via a metallic connection.

17. The CAN protection circuit of claim 16, wherein one of the first semiconductor device and the second semiconductor device is connected between a VCC terminal and a CAN High terminal, and
wherein the other of the first semiconductor device and the second semiconductor device is connected between the CAN High terminal and a GND terminal.

18. The CAN protection circuit of claim 16, further comprising:
a CAN transceiver having a VCC terminal, a CAN High terminal, a CAN Low terminal, and a GND terminal,
wherein the first semiconductor device is connected between the VCC terminal and the CAN High terminal, and
wherein the second semiconductor device is connected between the CAN Low terminal and the GND terminal.
